(19) United States
(12) Patent Application Publication
(10) Pub. No.: US 2024/0031060 A1
(43) Pub. Date: Jan. 25, 2024

(54) UNEQUAL PROTECTION OF DATA STREAMS

(71) Applicant: Weidong Yang, (US)

(72) Inventor: Weidong Yang, (US)

(21) Appl. No.: 18/245,735

(22) PCT Filed: Oct. 23, 2020
(86) PCT No.: PCT/CN2020/123369

§ 371 Date: Mar. 17, 2023

(51) Int. Cl. H04L 1/00; H04L 1/1812

(52) U.S. Cl. CPC H04L 1/007; H04L 1/0003; H04L 1/1812

(57) ABSTRACT

A user equipment (UE), next generation NodeB (gNB), or other network component can operate to configure unequal protection of data packets including a transport block (TB), a medium access control (MAC) packet data unit, or the like into a single physical layer encapsulation for transmission. TBs can be protected unequally within the encapsulation over a single physical channel (e.g., physical downlink shared channel (PDSCH), a physical uplink shared channel (PUSCH), or the like) with four or few spatial layers (e.g., two spatial layers). Spatial, time, or frequency resources can be unequally utilized among the different TBs or PDUs of the physical layer transmission, especially to prioritize or secure protection more to a specific TB over another within encapsulation for particular protocols or applications.

### FIELD

The present disclosure related to wireless technology, and more specifically, pertains to techniques for unequal protection of data streams.

### BACKGROUND

Mobile communication in the next generation wireless communication system, 5G, or new radio (NR) network will provide ubiquitous connectivity and access to information, as well as ability to share data, around the globe. High speed, high reliability and low latency are the key benefits that Communication Service Providers (CSPs) expect from 5G, for example. While high speed helps to upload and download video based content faster and in larger volumes, high reliability supports mission-critical services such as connected robotic factories, and low latency makes delay-critical services such as driverless cars a reality. These network benefits have been a prime reason behind 5G development: high speed (targeted at 10 Gbps) reducing latency down to less than a millisecond, and increasing reliability, and fully justify the use of 5G networks for life-critical services like remote surgery and autonomous driverless cars. With IoT opening up a new world of differentiated services including connected homes, automated factories and a massive build-up of small devices, there will be tremendous business opportunities for the IoT service providers as well as the CSPs. ITU has categorized 5G services have been categorized essentially as enhanced mobile broadband (eMBB), ultra-reliable and low-latency communications (uRLLC) or massive machine-type communications (mMTC) services. Each of these categories has varying needs for latency, reliability, and connectivity, with the success of uRLLC services being the most dependent on these parameters. With its ultra-reliable, low latency characteristics, uRLLC becomes the category of choice for new services like the autonomous car, industrial automation and extended reality (XR), including virtual reality (VR), augmented reality (AR), cloud gaming and other interactive video streaming applications, as well as modern edge computing significantly extending virtualization technology on edge servers. As such, updating data traffic models continue to be under study and there is a need to do so in a way that enables 5G next generation, new radio (NR) device to evolve based on third generation partnership project (3GPP) long term evolution (LTE)-Advanced technology with additional enhanced radio access technologies (RATs) that enable seamless and faster wireless connectivity solutions using orthogonal frequency division multiplexing (OFDM).

### BRIEF DESCRIPTION OF THE DRAWINGS

FIG. 1 is an exemplary block diagram illustrating an example of user equipment(s) (UEs) communicatively coupled a network with network components as peer devices useable in connection with various aspects described herein.

FIG. 2 illustrates a control plane protocol stack that can be implemented for operation of various embodiments and aspects described herein.

FIG. 3 is an exemplary a simplified block diagram of a user equipment (UE) wireless communication device or other network device/component (e.g., eNB, gNB) in accordance with various aspects.

FIG. 4 is a block diagram illustrating an example process flow for unequal data protection of data streams with different data units or transport blocks in a same physical layer transmission according to various aspects.

FIG. 5 is another block diagram illustrating an example process flow for unequal data protection of data streams with different data units or transport blocks in a physical layer transmission according to various aspects.

FIG. 6 is another block diagram illustrating an example process flow for unequal data protection of data streams with different data units or transport blocks in a physical layer transmission according to various aspects.

FIG. 7 is another block diagram illustrating an example process flow for unequal data protection of data streams with different data units or transport blocks in a physical layer transmission according to various aspects.

FIG. 8 is another block diagram illustrating an example process flow for unequal data protection of data streams with different data units or transport blocks in a physical layer transmission according to various aspects.

FIG. 9 is another block diagram illustrating an example process flow for unequal data protection of data streams with different data units or transport blocks in a physical layer transmission according to various aspects.

FIG. 10 is another block diagram illustrating a physical layer encapsulation for unequal data protection according to various aspects.

FIG. 11 is another block diagram illustrating an example process flow for unequal data protection of data streams with different data units or transport blocks in a physical layer transmission according to various aspects.

### DETAILED DESCRIPTION

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The present disclosure will now be described with reference to the attached drawing figures, wherein like (or similarly ending) reference numerals are used to refer to like elements throughout, and wherein the illustrated structures and devices are not necessarily drawn to scale. As utilized herein, terms “component,” “system,” “interface,” and the like are intended to refer to a computer-related entity, hardware, software (e.g., in execution), and/or firmware. For example, a component can be a processor (e.g., a microprocessor, a controller, or other processing device), a process running on a processor, a controller, an object, an executable, a program, a storage device, a computer, a tablet PC and/or a user equipment (e.g., mobile phone, etc.) with a processing device. By way of illustration, an application running on a server and the server can also be a component. One or more components can reside within a process, and a component can be localized on one computer and/or distributed between two or more computers. A set of elements or a set of other components can be described herein, in which the term “set” can be interpreted as “one or more.”

Further, these components can execute from various computer readable storage media having various data structures stored thereon such as with a module, for example. The components can communicate via local and/or remote processes such as in accordance with a signal having one or more data packets (e.g., data from one component interacting with another component in a local system, distributed system, and/or across a network, such as, the Internet, a local area network, a wide area network, or similar network with other systems via the signal).

As another example, a component can be an apparatus with specific functionality provided by mechanical parts operated by electric or electronic circuitry, in which the electric or electronic circuitry can be operated by a software application or a firmware application executed by one or more processors. The one or more processors can be internal or external to the apparatus and can execute at least a part of the software or firmware application. As yet another example, a component can be an apparatus that provides specific functionality through electronic components without mechanical parts; the electronic components can include one or more processors therein to execute software and/or firmware that confer(s), at least in part, the functionality of the electronic components.

Use of the word exemplary is intended to present concepts in a concrete fashion. As used in this application, the term “or” is intended to mean an inclusive “or” rather than an exclusive “or”. That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. In addition, the articles “a” and “an” as used in this application and the appended claims should generally be construed to mean “one or more” unless specified otherwise or clear from context to be directed to a singular form. Furthermore, to the extent that the terms “including”, “includes”, “having”, “has”, “with”, or variants thereof are used in either the detailed description and the claims, such terms are intended to be inclusive in a manner similar to the term “comprising.” Additionally, in situations wherein one or more numbered items are discussed (e.g., a “first X”, a “second X”, etc.), in general the one or more numbered items can be distinct or they can be the same, although in some situations the context can indicate that they are distinct or that they are the same.

As used herein, the term “circuitry” can refer to, be part of, or include an Application Specific Integrated Circuit (ASIC), an electronic circuit, a processor (shared, dedicated, or group), or associated memory (shared, dedicated, or group) operably coupled to the circuitry that execute one or more software or firmware programs, a combinational logic circuit, or other suitable hardware components that provide the described functionality. In some embodiments, the circuitry can be implemented in, or functions associated with the circuitry can be implemented by, one or more software or firmware modules. In some embodiments, circuitry can include logic, at least partially operable in hardware.

In consideration of the above, various aspects/embodiments are disclosed for communications in NR network devices (e.g., user equipment (UE), evolved NodeB (eNB), a next generation NodeB (gNB), a new radio (NR) base station (BS), or the like). With respect to LTE advanced and 5G NR devices, maintaining reliability, low latency and throughput in encoding and decoding streaming data can be enhanced by configuring unequal data partitioning in radio links. In particular, when a radio link is not handled to provide reliable low latency communication (RLLC) with high throughput through all data streams, it is important to protect the most critical ones to protect the UE quality of experience (QoE).

In an aspect, a gNB or UE, for example, can configure a physical layer encapsulation by multiplexing different transport blocks (TBs) for a physical layer transmission with an unequal protection between the different TBs of the physical layer encapsulation, such as on the user plane, packets in the evolved packet core (EPC) network encapsulated in specific EPC protocol and tunneled between a Core Network (CN) component (e.g., an Access and Mobility Management Function (AMF), a Session Management Function (SMF), a packet data network gateway (P-GW), or the like) and the e/gNB, a transmission time interval (TTI), or other parameter(s) for the encapsulation of data from higher layers into frames for transmission within a transmission opportunity on the radio link layer. Various resources, including spatial, frequency or time resources can be unequally used to secure protection of the TBs within the physical layer encapsulation for a single transmission burst. The physical layer encapsulation can be provided to transmitter circuitry that transmits (or receives) the data for a physical layer transmission with unequal protection of the TBs multiplexed therein. This physical layer transmission can be configured with four or less spatial layers via a physical channel (e.g., a physical downlink shared channel (PDSCH) or a physical uplink shared channel (PUSCH) in a next generation (NR) network.

Additional aspects and details of the disclosure are further described below with reference to figures.

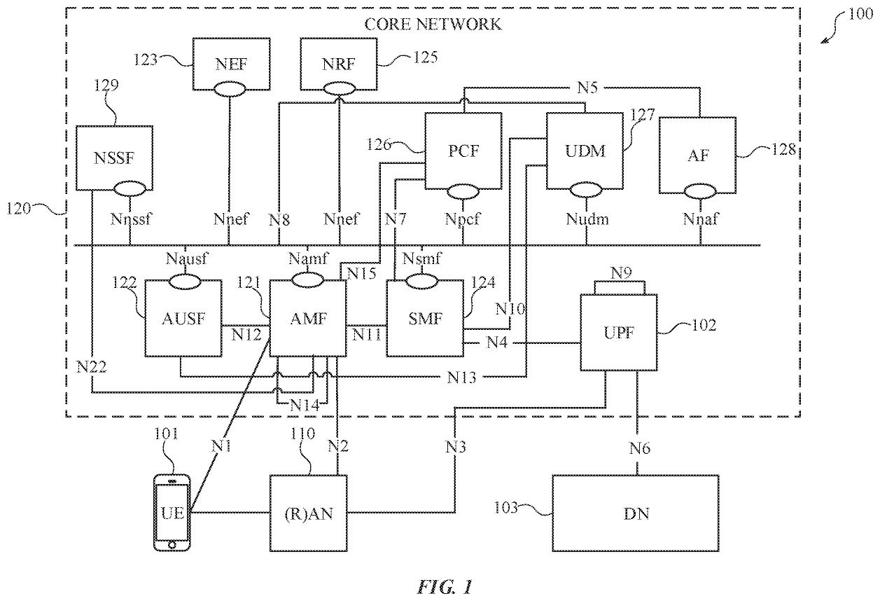

Embodiments described herein can be implemented into a system using any suitably configured hardware, software, or other component. FIG. 1 illustrates an architecture of a system 100 including a Core Network (CN) 120, for example a Fifth Generation (5G) CN (5GC), in accordance with various embodiments. The system 100 is shown to include a UE 101, which can be the same or similar to one or more other UEs discussed herein; a Third Generation Partnership Project (3GPP) Radio Access Network (Radio AN or RAN) or other (e.g., non-3GPP) AN, (R)AN 210, which can include one or more RAN nodes (e.g., Evolved Node B(s) (eNB(s)), next generation Node B(s) (gNB(s), and/or other nodes) or other nodes or access points; and a Data Network (DN) 203, which can be, for example, operator services, Internet access or third party services; and a Fifth Generation Core Network (5GC) 120. The 5GC 120 can comprise one or more of the following functions and network components: an Authentication Server Function (AUSF) 122; an Access and Mobility Management Function (AMF) 121; a Session Management Function (SMF) 124; a Network Exposure Function (NEF) 123; a Policy Control Function (PCF) 126; a Network Repository Function (NRF) 125; a Unified Data Management (UDM) 127; an Application Function (AF) 128; a User Plane (UP) Function (UPF) 102; and a Network Slice Selection Function (NSSF) 129.

In this example, one or more UEs 101 are illustrated as smartphones (e.g., handheld touchscreen mobile computing devices connectable to one or more cellular networks), but can comprise any mobile or non-mobile computing device, such as consumer electronics devices, cellular phones, smartphones, feature phones, tablet computers, wearable computer devices, personal digital assistants (PDAs), pagers, wireless handsets, desktop computers, laptop computers, in-vehicle infotainment (IVI), in-car entertainment (ICE) devices, an Instrument Cluster (IC), head-up display (HUD) devices, onboard diagnostic (OBD) devices, dashtop mobile equipment (DME), mobile data terminals (MDTs), Electronic Engine Management System (EEMS), electronic/engine control units (ECUs), electronic/engine control modules (ECMs), embedded systems, microcontrollers, control modules, engine management systems (EMS), networked or “smart” appliances, Machine Type Communication (MTC) devices, Machine to Machine (M2M), Internet of Things (IoT) devices, and/or the like.

In some embodiments, any of the UEs 101 can be IoT UEs, which can comprise a network access layer designed for low-power IoT applications utilizing short-lived UE connections. An IoT UE can utilize technologies such as M2M or MTC for exchanging data with an MTC server or device via a public land mobile network (PLMN), Proximity Services (ProSe) or Device-to-Device (D2D) communication, sensor networks, or IoT networks. The M2M or MTC exchange of data can be a machine-initiated exchange of data. An IoT network describes interconnecting IoT UEs, which can include uniquely identifiable embedded computing devices (within the Internet infrastructure), with short-lived connections. The IoT UEs can execute background applications (e.g., keep-alive messages, status updates, etc.) to facilitate the connections of the IoT network.

The UPF 102 can act as an anchor point for intra-RAT and inter-RAT mobility, an external Protocol Data Unit (PDU) session point of interconnect to DN 103, and a branching point to support multi-homed PDU session. The UPF 102 can also perform packet routing and forwarding, perform packet inspection, enforce the user plane part of policy rules, lawfully intercept packets (UP collection), perform traffic usage reporting, perform QoS handling for a user plane (e.g., packet filtering, gating, Uplink (UL)/Downlink (DL) rate enforcement), perform Uplink Traffic verification (e.g., Service Data Flow (SDF) to QoS flow mapping), transport level packet marking in the uplink and downlink, and perform downlink packet buffering and downlink data notification triggering. UPF 102 can include an uplink classifier to support routing traffic flows to a data network. The DN 103 can represent various network operator services, Internet access, or third-party services. DN 103 can include, or be similar to, an application server. The UPF 102 can interact with the SMF 124 via an N4 reference point between the SMF 124 and the UPF 102.

The AUSF 122 can store data for authentication of UE 101 and handle authentication-related functionality. The AUSF 122 can facilitate a common authentication framework for various access types. The AUSF 122 can communicate with the AMF 121 via an N12 reference point between the AMF 121 and the AUSF 122; and can communicate with the UDM 127 via an N13 reference point between the UDM 127 and the AUSF 122. Additionally, the AUSF 122 can exhibit an Nausf service-based interface.

The AMF 121 can be responsible for registration management (e.g., for registering UE 101, etc.), connection management, reachability management, mobility management, and lawful interception of AMF-related events, and access authentication and authorization. The AMF 121 can be a termination point for the N11 reference point between the AMF 121 and the SMF 124. The AMF 121 can provide transport for SM messages between the UE 101 and the SMF 124, and act as a transparent proxy for routing SM messages. AMF 121 can also provide transport for SMS messages between UE 101 and a Short Message Service (SMS) Function (SMSF) (not shown in FIG. 1). AMF 121 can act as Security Anchor Function (SEAF), which can include interaction with the AUSF 122 and the UE 101 and/or receipt of an intermediate key that was established as a result of the UE 101 authentication process. Where Universal Subscriber Identity Module (USIM) based authentication is used, the AMF 121 can retrieve the security material from the AUSF 122. AMF 121 can also include a Single-Connection Mode (SCM) function, which receives a key from the SEA that it uses to derive access-network specific keys. Furthermore, AMF 121 can be a termination point of a RAN Control Plane (CP) interface, which can include or be an N2 reference point between the (R)AN 110 and the AMF 121; and the AMF 121 can be a termination point of Non Access Stratum (NAS) (N1) signaling, and perform NAS ciphering and integrity protection.

AMF 121 can also support NAS signaling with a UE 101 over a non-3GPP (N3) Inter Working Function (IWF) interface. The N3IWF can be used to provide access to untrusted entities. N3IWF can be a termination point for the N2 interface between the (R)AN 110 and the AMF 121 for the control plane, and can be a termination point for the N3 reference point between the (R)AN 110 and the UPF 102 for the user plane. As such, the AMF 121 can handle N2 signaling from the SMF 124 and the AMF 121 for PDU sessions and QoS, encapsulate/de-encapsulate packets for Internet Protocol (IP) Security (IPSec) and N3 tunneling, mark N3 user-plane packets in the uplink, and enforce QoS corresponding to N3 packet marking taking into account QoS requirements associated with such marking received over N2. N3IWF can also relay uplink and downlink control-plane NAS signaling between the UE 101 and AMF 121 via an N1 reference point between the UE 101 and the AMF 121, and relay uplink and downlink user-plane packets between the UE 101 and UPF 102. The N3IWF also provides mechanisms for IPsec tunnel establishment with the UE 101. The AMF 121 can exhibit an Namf service-based interface, and can be a termination point for an N14 reference point between two AMFs 121 and an N17 reference point between the AMF 121 and a 5G Equipment Identity Register (5G-EIR) (not shown in FIG. 1).

The UE 101 can be registered with the AMF 121 in order to receive network services. Registration Management (RM) is used to register or deregister the UE 101 with the network (e.g., AMF 121), and establish a UE context in the network (e.g., AMF 121). The UE 101 can operate in an RM-REGISTERED state or an RM-DEREGISTERED state. In the RM-DEREGISTERED state, the UE 101 is not registered with the network, and the UE context in AMF 121 holds no valid location or routing information for the UE 101 so the UE 101 is not reachable by the AMF 121. In the RM-REGISTERED state, the UE 101 is registered with the network, and the UE context in AMF 121 can hold a valid location or routing information for the UE 101 so the UE 101 is reachable by the AMF 121. In the RM-REGISTERED state, the UE 101 can perform mobility Registration Update procedures, perform periodic Registration Update procedures triggered by expiration of the periodic update timer (e.g., to notify the network that the UE 101 is still active), and perform a Registration Update procedure to update UE capability information or to re-negotiate protocol parameters with the network, among others.

The AMF 121 can store one or more RM contexts for the UE 101, where each RM context is associated with a specific access to the network. The RM context can be a data structure, database object, etc. that indicates or stores, inter alia, a registration state per access type and the periodic update timer. The AMF 121 can also store a 5GC Mobility Management (MM) context that can be the same or similar to an (Enhanced Packet System (EPS))MM ((E)MM) context. In various embodiments, the AMF 121 can store a Coverage Enhancement (CE) mode B Restriction parameter of the UE 101 in an associated MM context or RM context. The AMF 121 can also derive the value, when needed, from the UE's usage setting parameter already stored in the UE context (and/or MM/RM context).

Connection Management (CM) can be used to establish and release a signaling connection between the UE 101 and the AMF 121 over the N1 interface. The signaling connection is used to enable NAS signaling exchange between the UE 101 and the CN 120, and comprises both the signaling connection between the UE and the AN (e.g., RRC connection or UE-N3IWF connection for non-3GPP access) and the N2 connection for the UE 101 between the AN (e.g., RAN 110) and the AMF 121. The UE 101 can operate in one of two CM states, CM-IDLE mode or CM-CONNECTED mode.

When the UE 101 is operating in the CM-IDLE state/mode, the UE 101 may have no NAS signaling connection established with the AMF 121 over the N1 interface, and there can be (R)AN 110 signaling connection (e.g., N2 and/or N3 connections) for the UE 101. When the UE 101 is operating in the CM-CONNECTED state/mode, the UE 101 can have an established NAS signaling connection with the AMF 121 over the N1 interface, and there can be a (R)AN 110 signaling connection (e.g., N2 and/or N3 connections) for the UE 101. Establishment of an N2 connection between the (R)AN 110 and the AMF 121 can cause the UE 101 to transition from CM-IDLE mode to CM-CONNECTED mode, and the UE 101 can transition from the CM-CONNECTED mode to the CM-IDLE mode when N2 signaling between the (R)AN 110 and the AMF 121 is released.

The SMF 124 can be responsible for Session Management (SM) (e.g., session establishment, modify and release, including tunnel maintain between UPF and AN node); UE IP address allocation and management (including optional authorization); selection and control of UP function; configuring traffic steering at UPF to route traffic to proper destination; termination of interfaces toward policy control functions; controlling part of policy enforcement and QoS; lawful intercept (for SM events and interface to Lawful Interception (LI) system); termination of SM parts of NAS messages; downlink data notification; initiating AN specific SM information, sent via AMF over N2 to AN; and determining Session and Service Continuity (SSC) mode of a session. SM can refer to management of a PDU session, and a PDU session or “session” can refer to a PDU connectivity service that provides or enables the exchange of PDUs between a UE 101 and a data network (DN) 103 identified by a Data Network Name (DNN). PDU sessions can be established upon UE 101 request, modified upon UE 101 and 5GC 120 request, and released upon UE 101 and 5GC 120 request using NAS SM signaling exchanged over the N1 reference point between the UE 101 and the SMF 124. Upon request from an application server, the 5GC 120 can trigger a specific application in the UE 101. In response to receipt of the trigger message, the UE 101 can pass the trigger message (or relevant parts/information of the trigger message) to one or more identified applications in the UE 101. The identified application(s) in the UE 101 can establish a PDU session to a specific DNN. The SMF 124 can check whether the UE 101 requests are compliant with user subscription information associated with the UE 101. In this regard, the SMF 124 can retrieve and/or request to receive update notifications on SMF 124 level subscription data from the UDM 127.

The SMF 124 can include the following roaming functionality: handling local enforcement to apply QoS Service Level Agreements (SLAs) (Visited Public Land Mobile Network (VPLMN)); charging data collection and charging interface (VPLMN); lawful intercept (in VPLMN for SM events and interface to LI system); and support for interaction with external DN for transport of signaling for PDU session authorization/authentication by external DN. An N16 reference point between two SMFs 124 can be included in the system 100, which can be between another SMF 124 in a visited network and the SMF 124 in the home network in roaming scenarios. Additionally, the SMF 124 can exhibit the Nsmf service-based interface.

The NEF 123 can provide means for securely exposing the services and capabilities provided by 3GPP network functions for third party, internal exposure/re-exposure, Application Functions (e.g., AF 128), edge computing or fog computing systems, etc. In such embodiments, the NEF 123 can authenticate, authorize, and/or throttle the AFs. NEF 123 can also translate information exchanged with the AF 128 and information exchanged with internal network functions. For example, the NEF 123 can translate between an AF-Service-Identifier and an internal 5GC information. NEF 123 can also receive information from other network functions (NFs) based on exposed capabilities of other network functions. This information can be stored at the NEF 123 as structured data, or at a data storage NF using standardized interfaces. The stored information can then be re-exposed by the NEF 123 to other NFs and AFs, and/or used for other purposes such as analytics. Additionally, the NEF 123 can exhibit an Nnef service-based interface.

The NRF 125 can support service discovery functions, receive NF discovery requests from NF instances, and provide the information of the discovered NF instances to the NF instances. NRF 125 also maintains information of available NF instances and their supported services. As used herein, the terms “instantiate,” “instantiation,” and the like can refer to the creation of an instance, and an “instance” can refer to a concrete occurrence of an object, which can occur, for example, during execution of program code. Additionally, the NRF 125 can exhibit the Nnrf service-based interface.

The PCF 126 can provide policy rules to control plane function(s) to enforce them, and can also support unified policy framework to govern network behavior. The PCF 126 can also implement an FE to access subscription information relevant for policy decisions in a UDR of the UDM 127. The PCF 126 can communicate with the AMF 121 via an N15 reference point between the PCF 126 and the AMF 121, which can include a PCF 126 in a visited network and the AMF 121 in case of roaming scenarios. The PCF 126 can communicate with the AF 128 via an N5 reference point between the PCF 126 and the AF 128; and with the SMF 124 via an N7 reference point between the PCF 126 and the SMF 124. The system 100 and/or CN 120 can also include an N24 reference point between the PCF 126 (in the home network) and a PCF 126 in a visited network. Additionally, the PCF 126 can exhibit an Npcf service-based interface.

The UDM 127 can handle subscription-related information to support the network entities' handling of communication sessions, and can store subscription data of UE 101. For example, subscription data can be communicated between the UDM 127 and the AMF 121 via an N8 reference point between the UDM 127 and the AMF. The UDM 127 can include two parts, an application Functional Entity (FE) and a Unified Data Repository (UDR) (the FE and UDR are not shown in FIG. 1). The UDR can store subscription data and policy data for the UDM 127 and the PCF 126, and/or structured data for exposure and application data (including Packet Flow Descriptions (PFDs) for application detection, application request information for multiple UEs 101) for the NEF 123. The Nudr service-based interface can be exhibited by the UDR 221 to allow the UDM 127, PCF 126, and NEF 123 to access a particular set of the stored data, as well as to read, update (e.g., add, modify), delete, and subscribe to notification of relevant data changes in the UDR. The UDM can include a UDM-FE, which is in charge of processing credentials, location management, subscription management and so on. Several different FEs can serve the same user in different transactions. The UDM-FE accesses subscription information stored in the UDR and performs authentication credential processing, user identification handling, access authorization, registration/mobility management, and subscription management. The UDR can interact with the SMF 124 via an N10 reference point between the UDM 127 and the SMF 124. UDM 127 can also support SMS management, wherein an SMS-FE implements similar application logic as discussed elsewhere herein. Additionally, the UDM 127 can exhibit the Nudm service-based interface.

The AF 128 can provide application influence on traffic routing, provide access to NEF 123, and interact with the policy framework for policy control. 5GC 120 and AF 128 can provide information to each other via NEF 123, which can be used for edge computing implementations. In such implementations, the network operator and third party services can be hosted close to the UE 101 access point of attachment to achieve an efficient service delivery through the reduced end-to-end latency and load on the transport network. For edge computing implementations, the 5GC can select a UPF 102 close to the UE 101 and execute traffic steering from the UPF 102 to DN 103 via the N6 interface. This can be based on the UE subscription data, UE location, and information provided by the AF 128. In this way, the AF 128 can influence UPF (re)selection and traffic routing. Based on operator deployment, when AF 128 is considered to be a trusted entity, the network operator can permit AF 128 to interact directly with relevant NFs. Additionally, the AF 128 can exhibit an Naf service-based interface.

The NSSF 129 can select a set of network slice instances serving the UE 101. The NSSF 129 can also determine allowed Network Slice Selection Assistance Information (NSSAI) and the mapping to the subscribed Single NSSAIs (S-NSSAIs), as appropriate. The NSSF 129 can also determine the AMF set to be used to serve the UE 101, or a list of candidate AMF(s) 121 based on a suitable configuration and possibly by querying the NRF 125. The selection of a set of network slice instances for the UE 101 can be triggered by the AMF 121 with which the UE 101 is registered by interacting with the NSSF 129, which can lead to a change of AMF 121. The NSSF 129 can interact with the AMF 121 via an N22 reference point between AMF 121 and NSSF 129; and can communicate with another NSSF 129 in a visited network via an N31 reference point (not shown in FIG. 1). Additionally, the NSSF 129 can exhibit an Nnssf service-based interface.

As discussed previously, the CN 120 can include an SMSF, which can be responsible for SMS subscription checking and verification, and relaying SM messages to/from the UE 101 to/from other entities, such as an SMS-Gateway Mobile services Switching Center (GMSC)/Inter-Working MSC (IWMSC)/SMS-router. The SMSF can also interact with AMF 121 and UDM 127 for a notification procedure that the UE 101 is available for SMS transfer (e.g., set a UE not reachable flag, and notifying UDM 127 when UE 101 is available for SMS).

The CN 120 can also include other elements that are not shown in FIG. 1, such as a Data Storage system/architecture, a 5G-EIR, a Security Edge Protection Proxy (SEPP), and the like. The Data Storage system can include a Structured Data Storage Function (SDSF), an Unstructured Data Storage Function (UDSF), and/or the like. Any NF can store and retrieve unstructured data into/from the UDSF (e.g., UE contexts), via N18 reference point between any NF and the UDSF (not shown in FIG. 1). Individual NFs can share a UDSF for storing their respective unstructured data or individual NFs can each have their own UDSF located at or near the individual NFs. Additionally, the UDSF can exhibit an Nudsf service-based interface (not shown in FIG. 1). The 5G-EIR can be an NF that checks the status of Permanent Equipment Identifier (PEI) for determining whether particular equipment/entities are blacklisted from the network; and the SEPP can be a non-transparent proxy that performs topology hiding, message filtering, and policing on inter-PLMN control plane interfaces.

Additionally, there can be many more reference points and/or service-based interfaces between the NF services in the NFs; however, these interfaces and reference points have been omitted from FIG. 1 for clarity. In one example, the CN 120 can include an Nx interface, which is an inter-CN interface between the MME (e.g., a non-5G MME) and the AMF 121 in order to enable interworking between CN 120 and a non-5G CN. Other example interfaces/reference points can include an N5g-EIR service-based interface exhibited by a 5G-EIR, an N27 reference point between the Network Repository Function (NRF) in the visited network and the NRF in the home network; and an N31 reference point between the NSSF in the visited network and the NSSF in the home network.

In embodiments, the UEs 101 can be configured to communicate using Orthogonal Frequency-Division Multiplexing (OFDM) communication signals with each other or with any of the RAN nodes 110 over a multicarrier communication channel in accordance with various communication techniques, such as, but not limited to, an OFDMA communication technique (e.g., for downlink communications) or a Single Carrier Frequency-Division Multiple Access (SC-FDMA) communication technique (e.g., for uplink and ProSe or sidelink communications), although the scope of the embodiments is not limited in this respect. The OFDM signals can comprise a plurality of orthogonal subcarriers.

In some embodiments, a downlink resource grid can be used for downlink transmissions from any of the RAN nodes 110 to the UEs 101, while uplink transmissions can utilize similar techniques. The grid can be a time-frequency grid, called a resource grid or time-frequency resource grid, which is the physical resource in the downlink in each slot. Such a time-frequency plane representation is a common practice for OFDM systems, which makes it intuitive for radio resource allocation. Each column and each row of the resource grid corresponds to one OFDM symbol and one OFDM subcarrier, respectively. The duration of the resource grid in the time domain corresponds to one slot in a radio frame. The smallest time-frequency unit in a resource grid is denoted as a resource element. Each resource grid comprises a number of resource blocks, which describe the mapping of certain physical channels to resource elements (REs). Each resource block comprises a collection of resource elements; in the frequency domain, this can represent the smallest quantity of resources that currently can be allocated. There are several different physical downlink channels that are conveyed using such resource blocks.

According to various embodiments, the UEs 101 and the RAN nodes 110 communicate data (for example, transmit and receive) data over a licensed medium (also referred to as the “licensed spectrum” and/or the “licensed band”) and an unlicensed shared medium (also referred to as the “unlicensed spectrum” and/or the “unlicensed band”). The licensed spectrum can include channels that operate in the frequency range of approximately 400 MHz to approximately 2.8 GHz, whereas the unlicensed spectrum can include the 5 GHz band.

Medium/carrier sensing operations can be performed according to a listen-before-talk (LBT) protocol. LBT is a mechanism whereby network devices/equipment senses a medium (e.g., a channel or carrier frequency) and transmits when the medium is sensed to be idle (or when a specific channel in the medium is sensed to be unoccupied). The medium sensing operation can include Clear Channel Assessment (CCA), which utilizes at least energy detection (ED) to determine the presence or absence of other signals on a channel in order to determine if a channel is occupied or clear. This LBT mechanism allows cellular/LAA networks to coexist with incumbent systems in the unlicensed spectrum and with other LAA networks. ED can include sensing RF energy across an intended transmission band for a period of time and comparing the sensed RF energy to a predefined or configured threshold.

In some implementations, the LBT procedure for downlink (DL) or uplink (UL) transmission bursts including physical downlink shared channel (PDSCH) or physical uplink shared channel (PUSCH) transmissions, respectively, can have an LAA contention window that is variable in length between X and Y extended CCA (ECCA) slots, where X and Y are minimum and maximum values for the contention window sizes (CWSs) for LAA. In one example, the minimum CWS for an LAA transmission can be 9 microseconds (μs); however, the size of the CWS and a maximum channel occupancy time (MCOT) (e.g., a transmission burst, or transmission opportunity) can be based on governmental regulatory requirements.

The LAA mechanisms are built upon carrier aggregation (CA) technologies of LTE-Advanced systems. In CA, each aggregated carrier is referred to as a component carrier (CC). A CC can have a bandwidth of 1.4, 2, 5, 10, 15 or 20 MHz and a maximum of about five CCs or otherwise can be aggregated, and therefore, a maximum aggregated bandwidth can be about 100 MHz, for example. In frequency division duplex (FDD) systems, the number of aggregated carriers can be different for DL and UL, where the number of UL CCs is equal to or lower than the number of DL component carriers. In some cases, individual CCs can have a different bandwidth than other CCs. In time division duplex (TDD) systems, the number of CCs as well as the bandwidths of each CC is usually the same for DL and UL.

CA also comprises individual serving cells to provide individual CCs. The coverage of the serving cells can differ, for example, because CCs on different frequency bands will experience different pathloss. A primary service cell or PCell can provide a primary component carrier (PCC) for both UL and DL, and can handle radio resource control (RRC) and non-access stratum (NAS) related activities. The other serving cells are referred to as SCells, and each SCell can provide an individual secondary component carrier (SCC) for both UL and DL. The SCCs can be added and removed as required, while changing the PCC can require the UE 101 to undergo a handover. In LAA, eLAA, and feLAA, some or all of the SCells can operate in the unlicensed spectrum (referred to as “LAA SCells”), and the LAA SCells are assisted by a PCell operating in the licensed spectrum. When a UE is configured with more than one LAA SCell, the UE can receive UL grants on the configured LAA SCells indicating different PUSCH starting positions within a same subframe.

The PDSCH carries user data and higher-layer signaling to the UEs 101. The physical downlink control channel (PDCCH) carries information about the transport format and resource allocations related to the PDSCH channel, among other things. It can also inform the UEs 101 about the transport format, resource allocation, and Hybrid Automatic Repeat Request (HARQ) information related to the uplink shared channel. Typically, downlink scheduling (assigning control and shared channel resource blocks to the UE 101b within a cell) can be performed at any of the RAN nodes 111 based on channel quality information fed back from any of the UEs 101. The downlink resource assignment information for scheduling grants (e.g., dynamic grant or the like) can be sent on the PDCCH used for (e.g., assigned to) each of the UEs 101.

The PDCCH uses control channel elements (CCEs) to convey the control information. Before being mapped to resource elements, the PDCCH complex-valued symbols can first be organized into quadruplets, which can then be permuted using a sub-block interleaver for rate matching. Each PDCCH can be transmitted using one or more of these CCEs, where each CCE can correspond to nine sets of four physical resource elements known as REGs. Four Quadrature Phase Shift Keying (QPSK) symbols can be mapped to each REG. The PDCCH can be transmitted using one or more CCEs, depending on the size of the DCI and the channel condition. There can be four or more different PDCCH formats defined in LTE with different numbers of CCEs (e.g., aggregation level, L=1, 2, 4, 8, or more).

The RAN 110 is shown to be communicatively coupled to a core network—in this embodiment, core network (CN) 120. The CN 120 can comprise a plurality of network elements 122, which are configured to offer various data and telecommunications services to customers/subscribers (e.g., users of UEs 101) who are connected to the CN 120 via the RAN 110. The components of the CN 120 can be implemented in one physical node or separate physical nodes including components to read and execute instructions from a machine-readable or computer-readable medium (e.g., a non-transitory machine-readable storage medium). In some embodiments, NFV can be utilized to virtualize any or all of the above-described network node functions via executable instructions stored in one or more computer-readable storage mediums. A logical instantiation of the CN 120 can be referred to as a network slice, and a logical instantiation of a portion of the CN 120 can be referred to as a network sub-slice. Network Function Virtualization (NFV) architectures and infrastructures can be used to virtualize one or more network functions, alternatively performed by proprietary hardware, onto physical resources comprising a combination of industry-standard server hardware, storage hardware, or switches. In other words, NFV systems can be used to execute virtual or reconfigurable implementations of one or more Evolved Packet Core (EPC) components/functions.

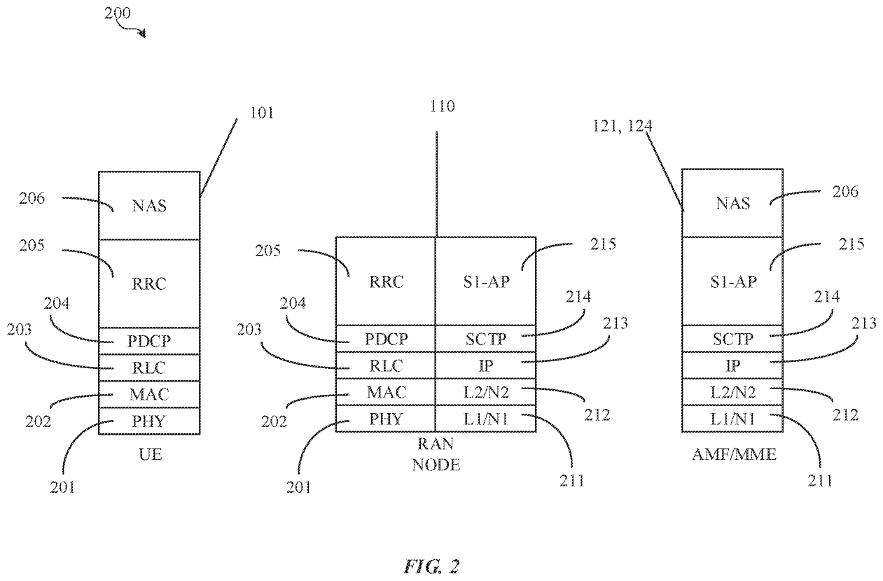

FIG. 2 is an illustration of a control plane protocol stack in accordance with various aspects described herein. In this embodiment, a control plane 200 is shown as a communications protocol stack between the UE 101, the RAN node 111, and the AMF 121, SMF 123, or a mobility management entity (MME).

The PHY layer 201 may transmit or receive information used by the MAC layer 202 over one or more air interfaces. The PHY layer 201 may further perform link adaptation or adaptive modulation and coding (AMC), power control, cell search (e.g., for initial synchronization and handover purposes), and other measurements used by higher layers, such as the RRC layer 205. The PHY layer 201 may still further perform error detection on the transport channels, forward error correction (FEC) coding/decoding of the transport channels, modulation/demodulation of physical channels, interleaving, rate matching, mapping onto physical channels, and Multiple Input Multiple Output (MIMO) antenna processing.

The MAC layer 202 may perform mapping between logical channels and transport channels, multiplexing of MAC service data units (SDUs) from one or more logical channels onto transport blocks (TB) to be delivered to PHY via transport channels, de-multiplexing MAC SDUs to one or more logical channels from transport blocks (TB) delivered from the PHY via transport channels, multiplexing MAC SDUs onto TBs, scheduling information reporting, error correction through hybrid automatic repeat request (HARQ), and logical channel prioritization.

The RLC layer 203 may operate in a plurality of modes of operation, including: Transparent Mode (TM), Unacknowledged Mode (UM), and Acknowledged Mode (AM). The RLC layer 203 may execute transfer of upper layer protocol data units (PDUs), error correction through automatic repeat request (ARQ) for AM data transfers, and concatenation, segmentation and reassembly of RLC SDUs for UM and AM data transfers. The RLC layer 203 may also execute re-segmentation of RLC data PDUs for AM data transfers, reorder RLC data PDUs for UM and AM data transfers, detect duplicate data for UM and AM data transfers, discard RLC SDUs for UM and AM data transfers, detect protocol errors for AM data transfers, and perform RLC re-establishment.

The PDCP layer 204 may execute header compression and decompression of IP data, maintain PDCP Sequence Numbers (SNs), perform in-sequence delivery of upper layer PDUs at re-establishment of lower layers, eliminate duplicates of lower layer SDUs at re-establishment of lower layers for radio bearers mapped on RLC AM, cipher and decipher control plane data, perform integrity protection and integrity verification of control plane data, control timer-based discard of data, and perform security operations (e.g., ciphering, deciphering, integrity protection, integrity verification, etc.).

The main services and functions of the RRC layer 205 may include broadcast of system information (e.g., included in Master Information Blocks (MIBs) or System Information Blocks (SIBs) related to the non-access stratum (NAS)), broadcast of system information related to the access stratum (AS), paging, establishment, maintenance and release of an RRC connection between the UE and E-UTRAN (e.g., RRC connection paging, RRC connection establishment, RRC connection modification, and RRC connection release), establishment, configuration, maintenance and release of point to point Radio Bearers, security functions including key management, inter radio access technology (RAT) mobility, and measurement configuration for UE measurement reporting. Said MIBs and SIBs may comprise one or more information elements (IEs), which may each comprise individual data fields or data structures.

The UE 101 and the RAN node 111 may utilize a Uu interface (e.g., an LTE-Uu interface) to exchange control plane data via a protocol stack comprising the PHY layer 201, the MAC layer 202, the RLC layer 203, the PDCP layer 204, and the RRC layer 205.

The non-access stratum (NAS) protocols 206 form the highest stratum of the control plane between the UE 101 and the MME 121. The NAS protocols 206 support the mobility of the UE 101 and the session management procedures to establish and maintain IP connectivity between the UE 101 and the P-GW or AMF.

The S1 Application Protocol (S1-AP) layer 215 may support the functions of the S1 interface and comprise Elementary Procedures (EPs). An EP is a unit of interaction between the RAN node 111 and the CN 120. The S1-AP layer services may comprise two groups: UE-associated services and non UE-associated services. These services perform functions including, but not limited to: E-UTRAN Radio Access Bearer (E-RAB) management, UE capability indication, mobility, NAS signaling transport, RAN Information Management (RIM), and configuration transfer.

The Stream Control Transmission Protocol (SCTP) layer (alternatively referred to as the SCTP/IP layer) 22 may ensure reliable delivery of signaling messages between the RAN node 111 and the MME 121 based, in part, on the IP protocol, supported by the IP layer 213. The L2/N2 layer 212 and the L1/N1 layer 211 may refer to communication links (e.g., wired or wireless) used by the RAN node and the AMF, SMF, or MME to exchange information. The RAN node 111 and the MME or AMF 121 may utilize an interface to exchange control plane data via a protocol stack comprising the L1/N1 layer 211, the L2/N2 layer 212, the IP layer 213, the SCTP layer 214, and the S1-AP layer 215, for example.

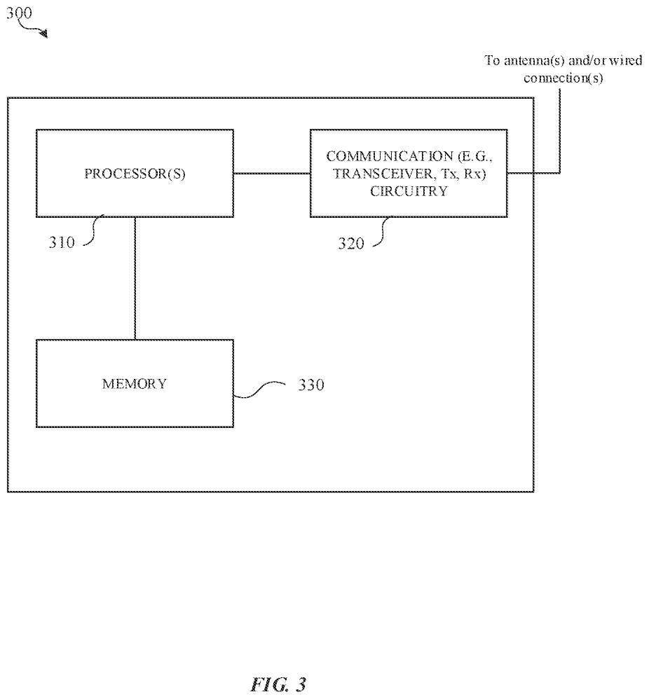

Referring to FIG. 3, illustrated is a block diagram of a user equipment (UE) device or other network device/component (e.g., gNB, eNB, or other participating network entity/component). The device 300 includes one or more processors 310 (e.g., one or more baseband processors) comprising processing circuitry and associated interface(s), transceiver circuitry 320 (e.g., comprising RF circuitry, which can comprise transmitter circuitry (e.g., associated with one or more transmit chains) and/or receiver circuitry (e.g., associated with one or more receive chains) that can employ common circuit elements, distinct circuit elements, or a combination thereof), and a memory 310 (which can comprise any of a variety of storage mediums and can store instructions and/or data associated with one or more of processor(s) 310 or transceiver circuitry 320).

In addition, the memory 330 (as well as other memory components discussed herein, e.g., memory, data storage, or the like) can comprise one or more machine-readable medium/media including instructions that, when performed by a machine or component herein cause the machine to perform acts of the method or of an apparatus or system for concurrent communication using multiple communication technologies according to embodiments and examples described herein. It is to be understood that aspects described herein can be implemented by hardware, software, firmware, or any combination thereof. When implemented in software, functions can be stored on or transmitted over as one or more instructions or code on a computer-readable medium (e.g., the memory described herein or other storage device). Computer-readable media includes both computer storage media and communication media including any medium that facilitates transfer of a computer program from one place to another. A storage media or a computer readable storage device can be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or other tangible and/or non-transitory medium, that can be used to carry or store desired information or executable instructions. Also, any connection can also be termed a computer-readable medium. For example, if software is transmitted from a website, server, or other remote source using a coaxial cable, fiber optic cable, twisted pair, digital subscriber line (DSL), or wireless technologies such as infrared, radio, and microwave, then coaxial cable, fiber optic cable, twisted pair, DSL, or wireless technologies such as infrared, radio, and microwave are included in the definition of medium. As described in greater detail below, system 400 can facilitate greater power efficiency for data streaming operations, including XR data streaming, including AR, VR, or other data streaming reporting/feedback based on a hierarchical (pre)coding scheme.

In an aspect, the UE/gNB device 300 can operate to configure by processing/generating/encoding/decoding a physical layer transmission comprising multiple different transport blocks (TBs) based on an unequal protection between the different TBs in a physical layer encapsulation (e.g., EPC packets, a transmission opportunity, MCOT, a single transmission burst, a TTI or other encapsulation protocol or related encapsulation parameter(s) for the encapsulation of data from higher layers into frames for transmission over the air. The physical layer transmission can be received, transmitter, or provide(d) with communication/transmitter circuitry 320 to similarly process/generate the physical layer transmission with four or less spatial layers via a physical channel in an NR network.

Multiple media access control (MAC) packet data units (PDUs) or TBs can be transmitted, for example, over a single physical channel (e.g., PDSCH or PUSCH) with four or less spatial layers together. Spatial multiplexing can be utilized to transmit multiple layers as multiple parallel transmission on a same time/frequency resource to the same device. Multiple antennas at the transmitter and receiver sides in combination can be used to process interference between the different layers. However, securing error loss in RLLC communications, for example, in data streaming with multiple layers can be further enhanced with unequal error protection of different TBs in one physical layer encapsulation being transmitted as differently coded signals being streamed from each of multiple antennas. One additional benefit with multiplexing multiple MAC PDUs into the same physical channel is to avoid inter-modulation distortion in uplink with an alternative transmission scheme where two PUSCHs carrying one MAC PDU respectively overlap in the time domain; with the disclosed approaches, the UE power amplifier can operate at higher transmission power compared with the case with the alternative approach.

Spatial layer signaling can multiplex transmissions of different data streams using a multi-stream transmission and increased throughput for spatial multiplexing in comparison with traditional single layer transmission. For XR related enhancements, for example, better support for video traffic can be an utmost importance, and key to enabling such enhancements. Low latency, high reliability and high throughput are challenging to be achieved at the same time. When a radio link is not handled to provide RLLC with high throughput for all data streams, it is important to protect the most critical ones to maintain the UE 300 experience. Thus, various transmission schemes for unequal error protection for different video streams can be configured, and also related to the HARQ feedback operation.

In an aspect, MAC PDUs or TBs in a same PDSCH/PUSCH can be transmitted with different protection levels, different error protection, different data protections among the different PDUs or TBs. Thus, a first TB, for example, can be configured in the encoding of the physical layer encapsulation with a different protection level that is greater than or more protected than a second TB in the same physical layer encapsulation. The UE 101 or gNB 110 (e.g., device 300) can operate to configure partitions of the different TBs of the physical layer encapsulation with different portions of at least one of: spatial, time or frequency resources among the different TBs of the physical layer encapsulation in order to protect one TB of a same physical layer encapsulation in a physical channel than the other. For example, different modulation bits can be used for different MAC PDUs (e.g., more reliable bits in 16 QAM used for a first MAC PDU or TB). Additionally, or alternatively, different MCS levels can be used among the different TBs or MAC PDUs. MAC PDUs can also be configured rather than TBs herein this disclosure, or vice versa. Additionally, or alternatively, different portions of frequency resources can be used for configuring the different TBs or MAC PDUs. Additionally, or alternatively, different spatial layers can be used for configuring the different TBs or MAC PDUs. Additionally, or alternatively, repeated transmissions of the TBs or MAC PDUs can be configured (e.g., a first TB can be configured to appear in more repetitions than the other within the same physical layer encapsulation or physical channel transmission).

While the methods or process flows are illustrated and described herein as a series of acts (process flow steps, events, or operations), it will be appreciated that the illustrated ordering of such acts are not to be interpreted in a limiting sense. For example, some acts may occur in different orders/concurrently with other acts or events apart from those illustrated/described herein. In addition, not all illustrated acts may be necessarily utilized to implement one or more aspects or embodiments of the description in this disclosure. Further, one or more of the acts depicted herein may be carried out in one or more separate acts/phases.

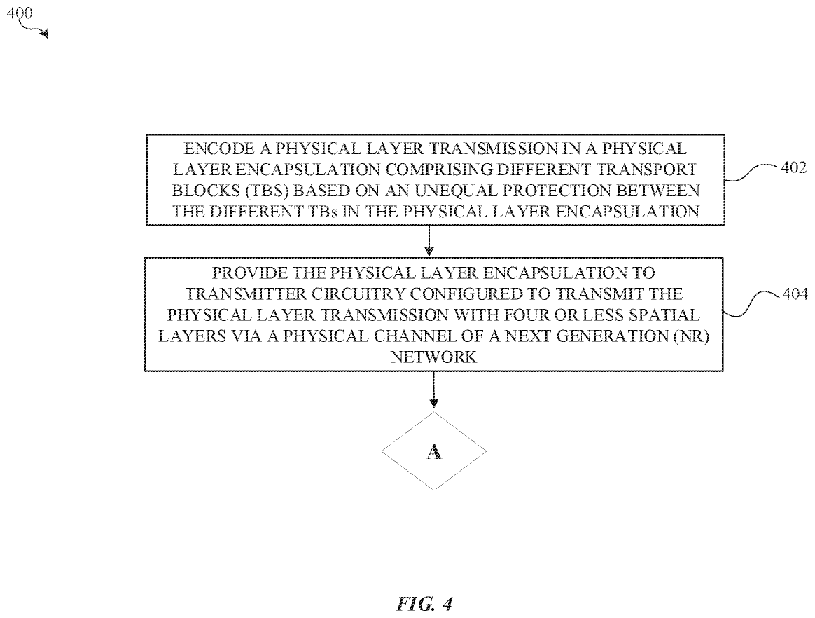

Referring to FIG. 4, illustrated is an example process flow 400 for configuring unequal protection of data streams or associated TBs of a physical layer encapsulation in an NR network between a gNB and UE (e.g., UE 101 or gNB 110) for wireless communications, such as ultra RLLC, RLLC, IoT or other connected components. At 402, the method 400 initiates with encoding a physical layer transmission in a physical layer encapsulation comprising different TBs based on unequal protection of the TBs in the physical layer encapsulation, in which the TBs can correspond to different data streams or different parameters, formatting, syntax, or other characteristics of one or more data streams.

At 404, the method further comprises providing the physical layer encapsulation (or transmission comprising the encapsulation) to transmitter circuitry to transmit the physical layer transmission via a physical channel, such as a PDSCH for downlink from a gNB 110 to the UE 101, or a PUSCH for uplink from a UE 101 to the gNB 110.

In an aspect, different TBs can be generated or encoded with different protection levels between at least a first TB and a second TB in the physical layer encapsulation. The different TBs that are encoded can be provided the physical layer encapsulation for the physical layer transmission via the PUSCH by the UE. When receiving the physical layer encapsulation with different TB therein as a single physical channel transmission from the gNB, the UE can process or decode these TBs multiplexed into the single physical layer encapsulation in response to receiving PDSCH. Likewise, a gNB can encode multiple TBs into a physical layer encapsulation for transmission via a single PDSCH transmission, while decoding the same configuration upon receiving a similar physical layer encapsulation multiplexed into one TB with multiple different TBs via the PUSCH. Each TB can be associated with a different data stream or coded data (e.g., scalable video coding, or the like) and configured with unequal protection within the encapsulation according to varies aspects/embodiments herein. The gNB or UE can configure the TBs in the encapsulation for transmission and reception based on four or less spatial layers.

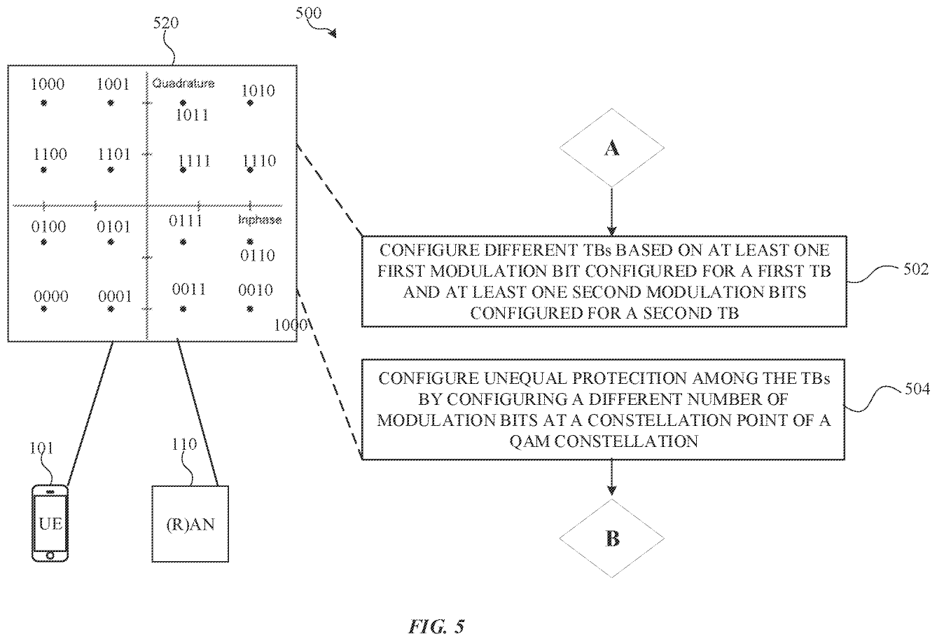

Referring to FIG. 5, illustrated is an example process flow 500 for configuring unequal protection of one or more data streams or associated TBs of a physical layer encapsulation in an NR network between a gNB and UE (e.g., UE 101 or gNB 110) for wireless communication (e.g., uRLLC, RLLC, or the like). Process flow 500 can flow from any one or more of the process flow acts of FIG. 4 as illustrated via A and connect to acts (502, 504) of process flow 500 at any position or order. The UE 101 and gNB 111 can comprise a constellation component 520 that is configured to encode/decode/generate/process modulation bits of a QAM constellation; although a 16 bit QAM constellation is illustrated, for example, any other configuration or number of bits can also be utilized herein. For example, the UE 101 or gNB 110 can be configured to encode if transmitting via PUSCH, or decode if receiving via PDSCH, the different TBs based on one or more first modulation bits associated with a first TB and one or more second modulation bits associated with a second TB at 502. At 504, the constellation component 520 can be further configured to configure unequal protection among the TBs by configuring a different number of modulation bits at a constellation point of the QAM constellation of the constellation component 520.

In aspect, the constellation component 520 can generate (encode) or process (decode) a first TB with a most reliable bit of the constellation. For example, a least significant bit of a constellation point can be utilized for the first TB to provide greater reliability or protection to the first TB than a second TB of the physical layer encapsulation in transmission. The constellation component 520 can further utilize one or more other bits of the same constellation to determine the unequal protection between the different TBs of a physical layer encapsulation for the second TB. Alternatively, or additionally, a different number of bits of a constellation point can be configured to different TBs to provide a greater or lesser protection between TBs of the physical layer encapsulation. For example, while the first TB is modulated based on a most reliable bit (e.g., LSB it or other more reliable bit based on signal strength, direction, or other parameter), the second TB can have two to four bits used for encoding or decoding within the physical layer encapsulation, for example. Although four bits are illustrated for each point, the disclosure is not limited necessarily to any specific number for utilizing the unequal protection of TBs or MAC PDUs, for example.

In an aspect, a determination can be made of a total TB size or total TB coded bit number according to a predefined formulation/function. Based on this total TB coded bit number, one or more percentages of the total TB coded bit number can be dynamically configured. A total TB coded bit number of the physical layer encapsulation can be configured based on a predefined formula, and then a first TB size of a first TB of the different TBs can be configured based on a first percentage of the total coded bit number. The second TB size of a second TB of the different TBs can be based on a second percentage. In one example, a total number of TB coded bits can be determined as 100 coded bits per PRB, in which there can be 20 PRBs in PDSCH, in total being 20×100 coded bits. The first TB and the second TB can be partitioned between the coded bits according to 25%+75%, or 50%+50%, etc. With 50%+50%, each has 10×100 coded bits, but the MCS level of each TB's can be different, so that, for example, a first TB has 100 information carrying bits, TB 2 has 200 information carrying bits, so though they may consume a similar number of coded bits, the reliability can still be configured to be different between them.

The percentage, reliability, total TB coded bit size, or other parameter(s) related to unequal protection of the different TBs can be determined according to the constellation component 520 of respective devices (UE 101, gNB 110), signaled via an RRC layer signaling dynamically per one or more physical layer transmissions, a MAC control element (MAC CE), higher layer signaling, or provided via a dynamic grant PUSCH for PUSCH transmission by a PDCCH. A configured grant CG Type 1, or CG Type 2, in which only the first transmission can be scheduled via a downlink control information (DCI), for example, can also enable the unequal protection for the UE 101 by the gNB 110. For PDSCH transmissions, a dynamic grant PDSCH (which is scheduled by a PDCCH), or DL SPS, in which only the first reception is scheduled by a DCI), can be utilized to configure the different TBs in the physical layer encapsulation with unequal protection. The aspects of this disclosure are not necessarily limited to any one type of signaling for configuring single physical channel transmission with unequal protection between TBs in the physical layer encapsulation. The constellation component 520 or processor of the UE 101/gNB 110, for example, can be configured to receive a parameter to determine the unequal protection among the different TBs of the physical layer encapsulation via the MAC CE, RRC signaling, or a higher layer signaling. This parameter(s) can be related to a spatial resource, a time resource, or a frequency resource for communications in an NR network, for example.

As discussed within this disclosure, the protection of the TBs can be configured based on a priority assigned to either TB based on the data stream type it is associated with or an additional data stream type, for example, with less or more resolution, or other parameter (e.g., a particular application, protocol, or format) of communication streaming. For example, in order to support a DL error protection for a video codecs a checkerboard pattern of data can be configured with two different types of data based on one or more semantic encodings, syntax formats or error detections. As such packages or physical layer encapsulations can be generated to target data or resources in TBs for different types of data. Thus, if one survives transmission, but the other is lost, a QoE can be maintained, especially within NR network communications for RLLC.

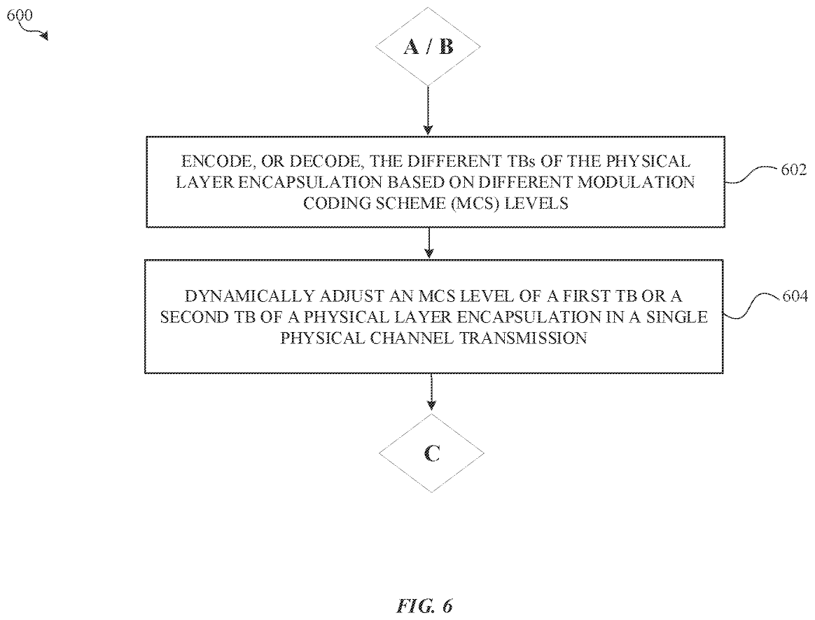

Referring to FIG. 6, illustrated is an example process flow 600 for configuring unequal protection of data streams or associated TBs of a physical layer encapsulation in an NR network between a gNB and UE (e.g., UE 101 or gNB 110) for wireless communication. Process flow 600 can flow from any one or more of the process flow acts of FIG. 4 or 5, as illustrated via A/B and connect to acts of process flow 600 at any position or order.

At 602, the different TBs can be encoded or decoded within the physical layer encapsulation based on different modulation coding schemes (MCS) levels. One or more first TBs of the different TBs can be encoded with a first MCS level and one or more second TBs of the different TBs with a second MCS level that is different than the first MCS level to provide different protections to the different TBs within the physical layer encapsulation. For example, a first TB in the physical layer encapsulation can be protected with an MCS level 2, and a second TB in the physical layer encapsulation protected with MCS level 5. A lower MCS level can provide a better protection, and thus, different levels of protections can be configured for the TBs multiplexed into a single physical layer encapsulation in a single physical channel.

At 604, an MCS level for configuring the different TBs of the physical layer encapsulation can be determined/adjusted dynamically. The signal or indication being signaled of an MCS level associated with the first or second TB of the different TBs can be generated or received for the unequal protection of TBs being encoded/decoded.

In an aspect, one MCS level can be signaled and another be derived based on an adjustment factor comprising a correlation to the first MCS level by a mathematical operation, for example, in order to have a differentiation between MCS levels of TBs in the encapsulation. In one example, a first MCS level can be based on/configured in a DCI and the second MCS level of another TB of the physical layer encapsulation can be a function of the first MCS level. Alternatively, or additionally, a pair of MCSs to encode/decode the different TBs can be determined via an RRC signaling associated with at least one of: a downlink (DL) semi-persistent scheduling (SPS) or an uplink (UL) configured grant (CG). Alternatively, or additionally, the different TBs of the physical layer encapsulation can be configured to be encoded, or decoded, based on a predefined pair of MCSs, respectively, in response to UL CG comprising a CG Type 1.

In another aspect, rather than utilizing a fixed MCS delta or adjustment factor, or MAC CE/RRC configured MCS level pairs, can configured similarly to a Transport Format Combination Indicator (TFCI) as in Universe Mobile Telecommunication Systems (UMTS) to enable the combination of transport blocks to be signaled.

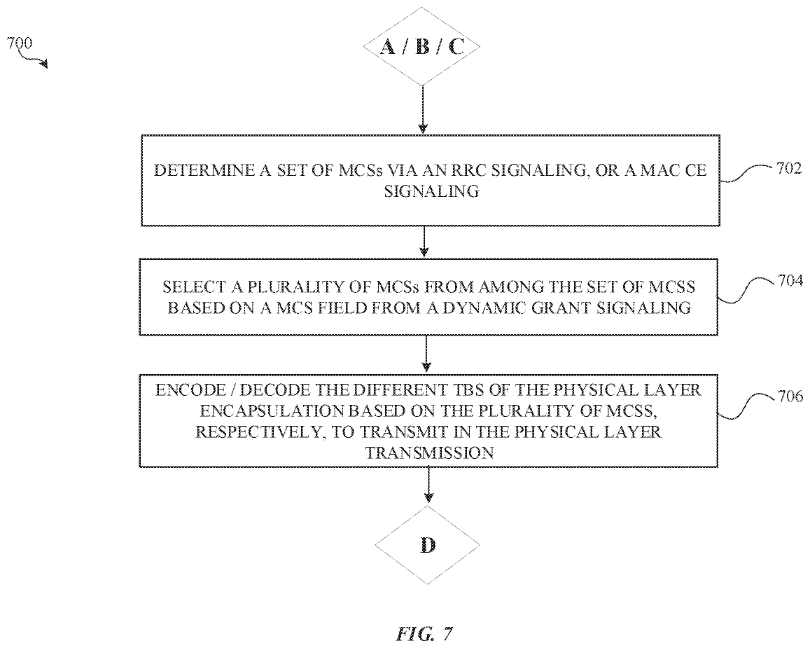

Referring to FIG. 7, illustrated is an example process flow 700 for configuring unequal protection of data streams or associated TBs of a physical layer encapsulation in an NR network between a gNB and UE (e.g., UE 101 or gNB 110) for wireless communication. Process flow 700 can flow from any one or more of the process flows acts of FIG. 4, 5, or 6, as illustrated via A/B/C and connect to acts of process flow 700 at any position or order.

At 702, the process flow comprises determining a list or a set of MCS levels via an RRC signaling, a higher layer signaling, a MAC CE signaling, or a DCI. The set can include one or more pairs, triplets, or otherwise sets of MCS levels configured to be associated for use with two or more different TBs being encapsulated in a physical layer encapsulation, for example.

At 704, a plurality of MCSs (e.g., pair, triplet, etc.) can be selected from among the set of MCS levels based on a MCS field from a dynamic grant signaling. For example, a combination pair or other grouping (e.g., MCS 2, MCS 5), (MCS 8, MCS 10), (MCS 10, MCS 12)) can be signaled that can comprises different sets of two or more MCS grouped together to correspond to the different TBs to be encoded/decoded in the physical layer encapsulation.

At 706, the different TBs of the physical layer encapsulation can be encoded based on the selected plurality of MCSs, respectively, to transmit in the physical layer transmission via a PUSCH, or decoded based on the indicated/selected plurality of MCSs, respectively, via a PDSCH.

In an aspect, an MCS level for the first TB can be signaled via a DCI. For example, if an “MCS field” indicates “1”, then (MCS 8, MCS 10) could selected for a first TB and a second TB, respectively. Here, the “MCS field” of any signaling can be repurposed to indicate a selected grouping (e.g., pair) of MCS levels among the set of MCS levels. Additionally, or alternatively, an MCS level for the second TB can be derived by an adjustment factor or a delta function with respect to the MCS level of the first TB.

In an aspect, the different TBs of the physical layer encapsulation can be encoded based on the selected plurality of MCSs, respectively, for the PUSCH with a CG Type 2, or decoded based on the plurality of MCSs, respectively, for the PDSCH with a DL semi-persistent scheduling (SPS).

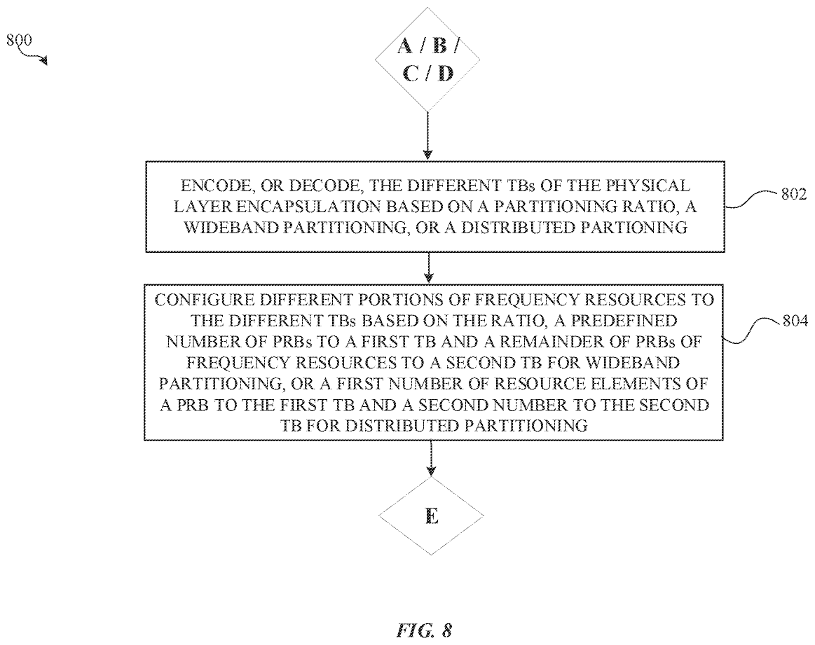

Referring to FIG. 8, illustrated is an example process flow 800 for configuring unequal protection of data streams or associated TBs of a physical layer encapsulation in an NR network between a gNB and UE (e.g., UE 101 or gNB 110) for wireless communication. Process flow 800 can flow from any one or more of the process flows acts of FIG. 4, 5, 6, or 7 as illustrated via A/B/C and connect to acts of process flow 700 at any position or order.

At 802, a partitioning ratio can be signaled (e.g., via DCI, or other signaling) to enable encoding or decoding of the different TBs of the physical layer encapsulation with the different portions based on the partitioning ratio. Alternatively, or additionally, the different TBs can be partitioned based on at least one of: a wideband partitioning or a distributed partitioning.

At 804, the process flow comprises configuring different portions of frequency resources to the different TBs in the encapsulation based on the partitioning ratio, a predefined number of physical resource blocks (PRBs) to a first TB and a remainder of PRBs of frequency resources to a second TB for wideband partitioning, or a first number of resource elements of a PRB to the first TB and a second number to the second TBs for distributed partitioning

In aspect, partitioning with a partitioning ratio, for example, can comprise a percentage of resources (e.g., frequency, spatial, or time) to a first TB (e.g., 60%) and the remainder of the granted resources to another TB (e.g., 40%). This partitioning can be signaled (e.g., a field of a DCI), determined on sight, or other wise signaled (RRC, or higher layer).

The wide partitioning can be associated to wideband or distributed partitioning as utilized in FDM for uRLLC. In wideband partitioning, a number of PRBs can be allocated to a first TB, while a remainder to the second TB multiplexed in one physical layer encapsulation of a transmission. With distributed partitioning, some resource elements (REs) in a PRB can be used for the first TB and some for the second TB.

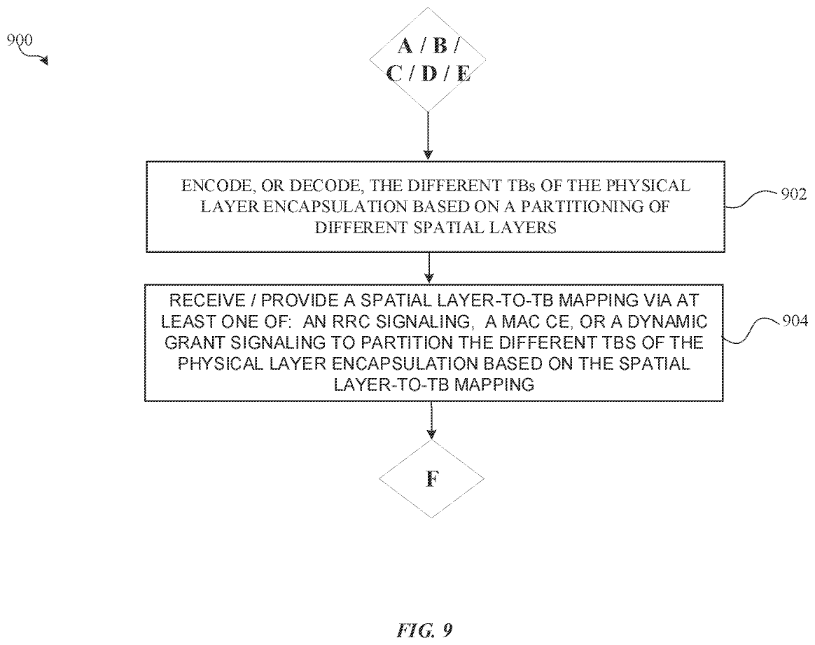

Referring to FIG. 9, illustrated is an example process flow 900 for configuring unequal protection of data streams or associated TBs of a physical layer encapsulation in an NR network between a gNB and UE (e.g., UE 101 or gNB 110) for wireless communication. Process flow 900 can flow from any one or more of the process flows acts of FIG. 4, 5, 6, 7, or 8 as illustrated via A/B/C/D/E and connect to acts of process flow 900 at any position or order.

At 902, different TBs of a physical layer encapsulation of a physical channel transmission can be partitioned with a partitioning of different spatial layers. For example, a first TB can be configured or associated with a first set of spatial layers that comprise a greater reliability than a second set of spatial layers associated with a second TB of the different TBs. The reliability can be a signal strength, direction, angle of depth, or other associated transmission parameter(s) for spatial layer transmissions. For example, the first set of spatial layers can comprise two spatial layers associated with one or more demodulation reference signal (DMRS) indices of the first TB and the second set of spatial layers comprises another two spatial layers. Alternatively, or additionally, the first set of spatial layers can comprise less spatial layers than the second set of spatial layers.

At 904, a UE (e.g., UE 101) can be configured receive a spatial layer-to-TB mapping via at least one of: an RRC signaling, a MAC CE, or a dynamic grant signaling to partition the different TBs of the physical layer encapsulation based on the spatial layer-to-TB mapping. Alternatively, or additionally, a gNB 110 can be configured to transmit such spatial layer-to-TB mapping to indicate a number or type of spatial layers to be associated with each TB of the physical layer encapsulation. For example, a signaling or spatial layer-to-TB mapping can indicate any one or more of the following for one or more physical layer transmissions with a single physical layer encapsulation being multiplexed with two TBs with four or less spatial layers: {spatial layers 1 & 3 for transport block 1, spatial layers 2 & 4 for transport block 2}, {spatial layers 1 & 2 for transport block 1, spatial layers 3 & 4 for transport block 2}.

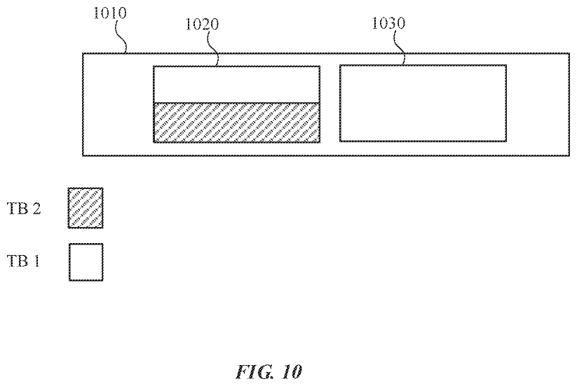

Referring to FIG. 10, illustrated is an example physical layer encapsulation 1010 with a first TB and a second TB combined with unequal protections or different protection levels (e.g., a first TB 1020 more heavily protected than a second TB 1030, or other TBs). Different TBs can be generated or processed with the unequal protection to the different TBs by partitioning repetitions among the physical layer encapsulation (e.g., a transmission opportunity, TTI, Frame, transmission burst, or other encapsulation) for a physical channel unequally based on a number of repetitions or slot resources. For example, a first TB can comprises more repetitions among repetition 1020 and 1030 than a second TB of the physical layer encapsulation, as well as include a greater number of resource elements in a slot or slots of each repetition to have different protection levels.

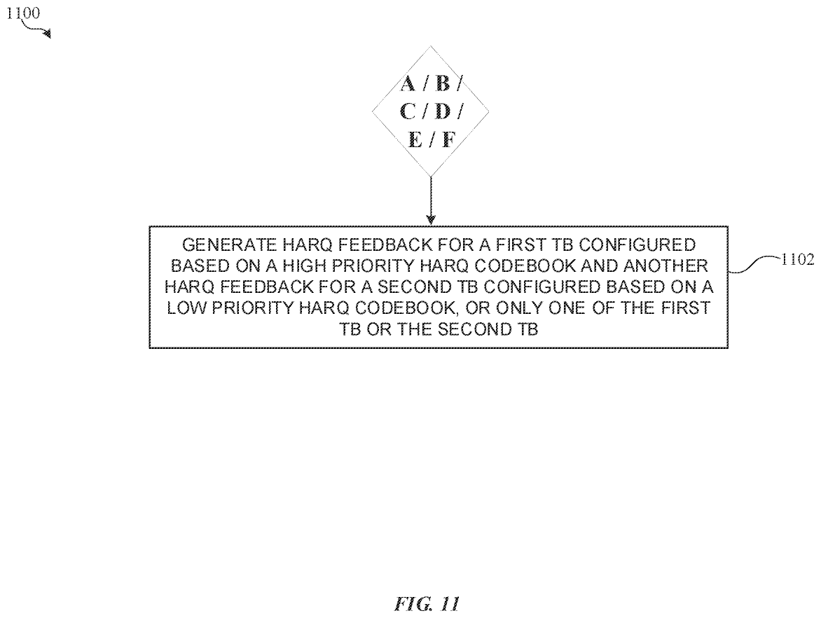

Referring to FIG. 11, illustrated is an example process flow 900 for configuring hybrid automatic repeat request (HARQ) feedback according to unequal protection of data streams or associated TBs of a physical layer encapsulation in an NR network between a gNB and UE (e.g., UE 101 or gNB 110) for wireless communication. Process flow 1100 can flow from any one or more of the process flows acts of FIG. 4, 5, 6, 7, 8 or 9 as illustrated via A/B/C/D/E/F and connect to acts of process flow 900 at any position or order.

At 1102, in response to receiving two or more TBs multiplexed into one physical channel, the UE 101 can generate a hybrid automatic repeat request (HARQ) feedback for a first TB configured based on a high priority HARQ codebook and another HARQ feedback for a second TB configured based on a low priority HARQ codebook that is lower in priority than the high priority HARQ codebook. Here, the priority of each TB can be treated equally for HARQ feedback. In an aspect, the UE 101 can generate HARQ feedback based on a bit width that is a function of a number of TBs (e.g., a maximum number of TBs) multiplexed into a physical downlink shared channel (PDSCH) for at least one of: a Type 1 HARQ codebook, a Type 2 HARQ codebook, or a Type 3 HARQ codebook.

Alternatively, or additionally, the UE 101 can generate the HARQ feedback only for the first TB configured based on the high priority HARQ codebook. Alternatively, or additionally, the UE 101 can generate the HARQ feedback only for the second TB configured based on the low priority HARQ codebook.

As it is employed in the subject specification, the term “processor” can refer to substantially any computing processing unit or device including, but not limited to including, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can refer to an integrated circuit, an application specific integrated circuit, a digital signal processor, a field programmable gate array, a programmable logic controller, a complex programmable logic device, a discrete gate or transistor logic, discrete hardware components, or any combination thereof designed to perform the functions and/or processes described herein. Processors can exploit nano-scale architectures such as, but not limited to, molecular and quantum-dot based transistors, switches and gates, in order to optimize space usage or enhance performance of mobile devices. A processor can also be implemented as a combination of computing processing units.

Examples (embodiments) can include subject matter such as a method, means for performing acts or blocks of the method, at least one machine-readable medium including instructions that, when performed by a machine (e.g., a processor with memory, an application-specific integrated circuit (ASIC), a field programmable gate array (FPGA), or the like) cause the machine to perform acts of the method or of an apparatus or system for concurrent communication using multiple communication technologies according to embodiments and examples described herein.

In example 1, a baseband processor of a network entity, configured to encode a physical layer transmission in a physical layer encapsulation comprising different transport blocks (TBs) based on an unequal protection between the different TBs in the physical layer encapsulation; and transmit the physical layer transmission via a physical channel of a next generation (NR) network.

In example 2, the baseband processor is further configured to encode the different TBs with different protection levels between at least a first TB and a second TB in the physical layer encapsulation and provide the physical layer encapsulation for the physical layer transmission via a physical uplink share channel (PUSCH), or decode other TBs multiplexed in another physical layer encapsulation in response to receiving a physical downlink shared channel (PDSCH).

In example 3, the baseband processor is further configured to encode the different TBs based on one or more first modulation bits associated with a first TB and one or more second modulation bits associated with a second TB, wherein the one or more first modulation bits comprise a higher reliability than the one or more second modulation bits at a constellation point of a QAM constellation.

In example 4, the baseband processor is further configured to encode the different TBs based on the unequal protection by associating the different TBs in the physical layer encapsulation with a different number of modulation bits at the constellation point.

In example 5, the baseband processor is further configured to encode, a first TB of the different TBs based on a least significant bit of a constellation point and a second TB of the different TBs based on one or more remaining bits of the constellation point.

In example 6, the baseband processor is further configured to determine a total TB coded bit number of the physical layer encapsulation based on a predefined formula, and a first TB size of a first TB of the different TBs based on a first percentage of the total TB coded bit number and a second TB size of a second TB of the different TBs based on a second percentage of the total TB coded bit number.

In example 7, the baseband processor is further configured to receive a parameter to determine the unequal protection among the different TBs of the physical layer encapsulation via a media access control (MAC) control element (MAC CE), a radio resource control (RRC) signaling, or a higher layer signaling.

In example 8, the baseband processor is further configured to encode the different TBs of the physical layer encapsulation based on different modulation coding scheme (MCS) levels by encoding one or more first TBs of the different TBs with a first MCS level and one or more second TBs of the different TBs with a second MCS level that is different than the first MCS level to provide different protections to the different TBs within the physical layer encapsulation.

In example 9, the baseband processor is further configured to determine the first MCS level based on a downlink control information (DCI) and the second MCS level as a function of the first MCS level.

In example 10, the baseband processor is further configured to determine a pair of MCSs to encode the different TBs via an RRC signaling associated with at least one of: a downlink (DL) semi-persistent scheduling (SPS) or an uplink (UL) configured grant (CG).

In example 11, the baseband processor is further configured to encode, the different TBs of the physical layer encapsulation based on a predefined pair of MCSs, respectively, in response to an UL CG comprising a CG Type 1.

In example 12, the baseband processor is further configured to: determine a set of MCSs via an RRC signaling, or a MAC CE signaling; select a plurality of MCSs from among the set of MCSs based on a MCS field from a dynamic grant signaling; and encode the different TBs of the physical layer encapsulation based on the plurality of MCSs, respectively, to transmit in the physical layer transmission via a physical uplink shared channel (PUSCH), or decode other TBs multiplexed in another physical layer encapsulation based on the plurality of MCSs, respectively, via a physical downlink shared channel (PDSCH).

In example 13, the baseband processor is further configured to encode the different TBs of the physical layer encapsulation based on the plurality of MCSs, respectively, for the PUSCH with a CG Type 2, or decode the other TBs of the another physical layer encapsulation based on the plurality of MCSs, respectively, for the PDSCH with a DL semi-persistent scheduling (SPS).

In example 14, the baseband processor is further configured to partition the different TBs of the physical layer encapsulation with different portions of at least one of: spatial, time or frequency resources among the different TBs of the physical layer encapsulation.

In example 15, the baseband processor is further configured to receive a partitioning ratio in a DCI, and encode the different TBs of the physical layer encapsulation with the different portions based on the partitioning ratio.

In example 16, the baseband processor is further configured to partition the different TBs based on at least one of: a wideband partitioning or a distributed partitioning.

In example 17, the wideband partitioning comprises configuring a predefined number of physical resource blocks (PRBs) to a first TB of the different TBs and a remainder of PRBs of frequency resources to a second TB of the different TBs, and the distributed partitioning comprises configuring a first number of resource elements of a PRB to the first TB and a second number of resource elements of the PRB to the second TB.

In example 18, the baseband processor is further configured to partition different spatial layers with the different TBs of the physical layer encapsulation, wherein a first TB is associated with a first set of spatial layers comprising a greater reliability than a second set of spatial layers associated with a second TB of the different TBs.

In example 19, the first set of spatial layers comprises two spatial layers associated with one or more demodulation reference signal (DMRS) indices of the first TB and the second set of spatial layers comprises another two spatial layers, or the first set of spatial layers comprises less spatial layers than the second set of spatial layers.

In example 20, the baseband processor is further configured to receive a spatial layer-to-TB mapping via at least one of: an RRC signaling, a MAC CE, or a dynamic grant signaling to partition the different TBs of the physical layer encapsulation based on the spatial layer-to-TB mapping.

In example 21, the baseband processor is further configured to generate the unequal protection to the different TBs by partitioning repetitions among a transmission opportunity unequally, wherein a first TB comprises more repetitions than a second TB of the physical layer encapsulation.

In example 22, the first TB comprises a greater amount of resource elements among the repetitions than the second TB.

In example 23, the processor is further configured to: in response to transmitting two or more TBs multiplexed into the physical layer encapsulation via one physical channel: receive a hybrid automatic repeat request (HARQ) feedback for a first TB configured based on a high priority HARQ codebook and another HARQ feedback for a second TB configured based on a low priority HARQ codebook that is lower in priority than the high priority HARQ codebook; receive the HARQ feedback only for the first TB configured based on the high priority HARQ codebook; or receive the HARQ feedback only for the second TB configured based on the low priority HARQ codebook.

In example 24, the network entity comprises a user equipment (UE).

In example 2, the network entity comprises a base station.

In example 26, a baseband processor of a network entity, configured to: receive the physical layer transmission via a physical channel in a next generation (NR) network; and decode a physical layer encapsulation by multiplexing different transport blocks (TBs) for a physical layer transmission based on an unequal protection between the different TBs of the physical layer encapsulation.

In example 27, the baseband processor is further configured to decode a first TB of the different TBs based on a first bit or a least significant bit that is more reliable than other bits of a constellation point and a second TB of the different TBs based on one or more other bits of the constellation point to determine the unequal protection among the different TBs in the physical layer encapsulation.

In example 28, the baseband processor is further configured to determine a first TB size of a first TB of the different TBs based on a first percentage of a total TB coded bit number and a second TB size of a second TB of the different TBs based on a second percentage of the total TB coded bit number.

In example 29, the baseband processor is further configured to determine a parameter to encode the unequal protection among the different TBs of the physical layer encapsulation based on a media access control (MAC) control element (MAC CE), a radio resource control (RRC) signaling, or a higher layer signaling.

In example 30, the baseband processor is further configured to decode the different TBs of the physical layer encapsulation based on different modulation coding scheme (MCS) levels associated with the different TBs, or provide a downlink control information (DCI) comprising an indication of an MCS level for multiplexing a first TB with a second TB associated with the different MCS levels of a physical layer encapsulation via a physical uplink shared channel (PUSCH) or a physical downlink shared channel (PDSCH).

In example 31, the processor is further configured to determine a pair of MCSs to encode the different TBs via an RRC signaling associated with at least one of: a downlink (DL) semi-persistent scheduling (SPS) or an uplink (UL) configured grant (CG).

In example 32, the processor is further configured to: determine a set of MCSs via an RRC signaling, or a MAC CE signaling; select a plurality of MCSs from among the set of MCSs based on an MCS field for a dynamic grant signaling; and configure the different TBs of the physical layer encapsulation based on the plurality of MCSs, respectively, to transmit the physical layer transmission for a physical uplink shared channel (PUSCH), or configure other TBs multiplexed in another physical layer encapsulation based on the plurality of MCSs, respectively, for a physical downlink shared channel (PDSCH).

In example 33, the processor is further configured to encode the different TBs of the physical layer encapsulation based on the plurality of MCSs, respectively, for the PDSCH with a configured grant (CG) Type 2, or decode the other TBs of the another physical layer encapsulation based on the plurality of MCSs, respectively, for the PUSCH with a downlink (DL) semi-persistent scheduling (SPS).

In example 34, wherein the processor is further configured to partition the different TBs of the physical layer encapsulation with different portions of at least one of: spatial resources, time resources, or frequency resources.

In example 35, the processor is further configured to partition the different TBs based on at least one of: a wideband partitioning or a distributed partitioning, wherein the wideband partitioning comprises configuring a predefined number of physical resource blocks (PRBs) to a first TB of the different TBs and a remainder of PRBs of frequency resources to a second TB of the different TBs, wherein the distributed partitioning comprises configuring a first number of resource elements of a PRB to the first TB and a second number of resource elements of the PRB to the second TB.

In example 36, wherein the processor is further configured to partition different spatial layers with the different TBs in the physical layer encapsulation, wherein a first TB is configured with a first set of spatial layers comprising a greater reliability than a second set of spatial layers configured with a second TB of the different TBs.

In example 37, a first set of spatial layers comprises at least two spatial layers configured with one or more demodulation reference signal (DMRS) indices for a first TB and a second set of spatial layers comprises two or less spatial layers for a second TB of the different TBs.

In example 38, wherein the processor is further configured to generate a spatial layer-to-TB mapping to partition the different TBs of the physical layer encapsulation based on the spatial layer-to-TB mapping for the unequal protection.

In example 39, the processor is further configured to generate the unequal protection to the different TBs by partitioning repetitions or slot resources among a transmission opportunity unequally, wherein a first TB comprises more repetitions or slot resources than a second TB of the physical layer encapsulation.

In example 40, wherein the baseband processor is further configured to: generate a hybrid automatic repeat request (HARQ) feedback for a first TB configured based on a high priority HARQ codebook and another HARQ feedback for a second TB configured based on a low priority HARQ codebook that is lower in priority than the high priority HARQ codebook; generate the HARQ feedback only for the first TB configured based on the high priority HARQ codebook; or generate the HARQ feedback only for the second TB configured based on the low priority HARQ codebook.

In example 41, the baseband processor is further configured to generate HARQ feedback based on a bit width that is a function of a number of TBs multiplexed into a physical downlink shared channel (PDSCH) for at least one of: a Type 1 HARQ codebook, a Type 2 HARQ codebook, or a Type 3 HARQ codebook.

In example 42, wherein the network entity comprises a user equipment (UE).

In example 43, wherein the network entity comprises a bast station.

In example 44, a method of a network entity comprising: processing, via a processor, a physical layer transmission comprising different transport blocks (TBs) multiplexed into a physical layer encapsulation with an unequal protection among the different TBs; and transmitting, via the processor, the physical layer transmission to transmitter circuitry that transmits the physical layer transmission based on four or less spatial layers in a next generation (NR) network.

In example 45, further comprising: encoding a first TB of the different TBs based on a first bit or a least significant bit that is more reliable than other bits of a constellation point and a second TB of the different TBs based on one or more of the other bits of the constellation point to generate the unequal protection among the different TBs.

Moreover, various aspects or features described herein can be implemented as a method, apparatus, or article of manufacture using standard programming and/or engineering techniques. The term “article of manufacture” as used herein is intended to encompass a computer program accessible from any computer-readable device, carrier, or media. For example, computer-readable media can include but are not limited to magnetic storage devices (e.g., hard disk, floppy disk, magnetic strips, etc.), optical disks (e.g., compact disk (CD), digital versatile disk (DVD), etc.), smart cards, and flash memory devices (e.g., EPROM, card, stick, key drive, etc.). Additionally, various storage media described herein can represent one or more devices and/or other machine-readable media for storing information. The term “machine-readable medium” can include, without being limited to, wireless channels and various other media capable of storing, containing, and/or carrying instruction(s) and/or data. Additionally, a computer program product can include a computer readable medium having one or more instructions or codes operable to cause a computer to perform functions described herein.

Communications media embody computer-readable instructions, data structures, program modules or other structured or unstructured data in a data signal such as a modulated data signal, e.g., a carrier wave or other transport mechanism, and includes any information delivery or transport media. The term “modulated data signal” or signals refers to a signal that has one or more of its characteristics set or changed in such a manner as to encode information in one or more signals. By way of example, and not limitation, communication media include wired media, such as a wired network or direct-wired connection, and wireless media such as acoustic, RF, infrared and other wireless media.

An exemplary storage medium can be coupled to processor, such that processor can read information from, and write information to, storage medium. In the alternative, storage medium can be integral to processor. Further, in some aspects, processor and storage medium can reside in an ASIC. Additionally, ASIC can reside in a user terminal. In the alternative, processor and storage medium can reside as discrete components in a user terminal. Additionally, in some aspects, the processes and/or actions of a method or algorithm can reside as one or any combination or set of codes and/or instructions on a machine-readable medium and/or computer readable medium, which can be incorporated into a computer program product.

In this regard, while the disclosed subject matter has been described in connection with various embodiments and corresponding Figures, where applicable, it is to be understood that other similar embodiments can be used or modifications and additions can be made to the described embodiments for performing the same, similar, alternative, or substitute function of the disclosed subject matter without deviating therefrom. Therefore, the disclosed subject matter should not be limited to any single embodiment described herein, but rather should be construed in breadth and scope in accordance with the appended claims below.

In particular regard to the various functions performed by the above described components (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure. In addition, while a particular feature can have been disclosed with respect to only one of several implementations, such feature can be combined with one or more other features of the other implementations as can be desired and advantageous for any given or particular application.

1. A baseband processor of a network entity, configured to
encode a physical layer transmission in a physical layer encapsulation comprising different transport blocks (TBs) based on an unequal protection between the different TBs in the physical layer encapsulation; and
transmit the physical layer transmission via a physical channel of a next generation (NR) network.

2. The baseband processor of claim 1, wherein the baseband processor is further configured to encode the different TBs with different protection levels between at least a first TB and a second TB in the physical layer encapsulation and provide the physical layer encapsulation for the physical layer transmission via a physical uplink share channel (PUSCH), or decode other TBs multiplexed in another physical layer encapsulation in response to receiving a physical downlink shared channel (PDSCH).

3. The baseband processor of claim 1, wherein the baseband processor is further configured to encode the different TBs based on one or more first modulation bits associated with a first TB and one or more second modulation bits associated with a second TB, wherein the one or more first modulation bits comprise a higher reliability than the one or more second modulation bits at a constellation point of a QAM constellation, and based on the unequal protection by associating the different TBs in the physical layer encapsulation with a different number of modulation bits at the constellation point.

4. (canceled)

5. The baseband processor of claim 1, wherein the baseband processor is further configured to encode, a first TB of the different TBs based on a least significant bit of a constellation point and a second TB of the different TBs based on one or more remaining bits of the constellation point.

6. The baseband processor of claim 1, wherein the baseband processor is further configured to determine a total TB coded bit number of the physical layer encapsulation based on a predefined formula, and a first TB size of a first TB of the different TBs based on a first percentage of the total TB coded bit number and a second TB size of a second TB of the different TBs based on a second percentage of the total TB coded bit number.

7. The baseband processor of claim 1, wherein the baseband processor is further configured to receive a parameter to determine the unequal protection among the different TBs of the physical layer encapsulation via a media access control (MAC) control element (MAC CE), a radio resource control (RRC) signaling, or a higher layer signaling.

8. The baseband processor of claim 1, wherein the baseband processor is further configured to encode the different TBs of the physical layer encapsulation based on different modulation coding scheme (MCS) levels by encoding one or more first TBs of the different TBs with a first MCS level and one or more second TBs of the different TBs with a second MCS level that is different than the first MCS level to provide different protections to the different TBs within the physical layer encapsulation.

9. (canceled)

10. (canceled)

11. (canceled)

12. The baseband processor of claim 8, wherein the baseband processor is further configured to:
determine a set of MCSs via an RRC signaling, or a MAC CE signaling;
select a plurality of MCSs from among the set of MCSs based on a MCS field from a dynamic grant signaling; and
encode the different TBs of the physical layer encapsulation based on the plurality of MCSs, respectively, to transmit in the physical layer transmission via a physical uplink shared channel (PUSCH), or decode other TBs multiplexed in another physical layer encapsulation based on the plurality of MCSs, respectively, via a physical downlink shared channel (PDSCH).

13. (canceled)

14. The baseband processor of claim 1, wherein the baseband processor is further configured to partition the different TBs of the physical layer encapsulation with different portions of at least one of: spatial, time or frequency resources among the different TBs of the physical layer encapsulation.

15. (canceled)

16. The baseband processor of claim 1, wherein the baseband processor is further configured to partition the different TBs based on at least one of: a wideband partitioning or a distributed partitioning, wherein the wideband partitioning comprises configuring a predefined number of physical resource blocks (PRBs) to a first TB of the different TBs and a remainder of PRBs of frequency resources to a second TB of the different TBs, and the distributed partitioning comprises configuring a first number of resource elements of a PRB to the first TB and a second number of resource elements of the PRB to the second TB.

17. (canceled)

18. The baseband processor of claim 1, wherein the baseband processor is further configured to partition different spatial layers with the different TBs of the physical layer encapsulation, wherein a first TB is associated with a first set of spatial layers comprising a greater reliability than a second set of spatial layers associated with a second TB of the different TBs, wherein the first set of spatial layers comprises two spatial layers associated with one or more demodulation reference signal (DMRS) indices of the first TB and the second set of spatial layers comprises another two spatial layers, or the first set of spatial layers comprises less spatial layers than the second set of spatial layers.

19. (canceled)

20. The baseband processor of claim 1, wherein the baseband processor is further configured to receive a spatial layer-to-TB mapping via at least one of: an RRC signaling, a MAC CE, or a dynamic grant signaling to partition the different TBs of the physical layer encapsulation based on the spatial layer-to-TB mapping.

21. The baseband processor of claim 1, wherein the baseband processor is further configured to generate the unequal protection to the different TBs by partitioning repetitions among a transmission opportunity unequally, wherein a first TB comprises more repetitions than a second TB of the physical layer encapsulation.

22. (canceled)

23. The baseband processor of claim 1, wherein the processor is further configured to:
in response to transmitting two or more TBs multiplexed into the physical layer encapsulation via one physical channel:
receive a hybrid automatic repeat request (HARQ) feedback for a first TB configured based on a high priority HARQ codebook and another HARQ feedback for a second TB configured based on a low priority HARQ codebook that is lower in priority than the high priority HARQ codebook;
receive the HARQ feedback only for the first TB configured based on the high priority HARQ codebook; or
receive the HARQ feedback only for the second TB configured based on the low priority HARQ codebook.

24. (canceled)

25. (canceled)

26. A baseband processor of a network entity, configured to:
receive a physical layer transmission via a physical channel in a next generation (NR) network; and
decode a physical layer encapsulation by multiplexing different transport blocks (TBs) for a physical layer transmission based on an unequal protection between the different TBs of the physical layer encapsulation.

27. The baseband processor of claim 26, wherein the baseband processor is further configured to decode a first TB of the different TBs based on a first bit or a least significant bit that is more reliable than other bits of a constellation point and a second TB of the different TBs based on one or more other bits of the constellation point to determine the unequal protection among the different TBs in the physical layer encapsulation.

28. The baseband processor of claim 26, wherein the baseband processor is further configured to determine a first TB size of a first TB of the different TBs based on a first percentage of a total TB coded bit number and a second TB size of a second TB of the different TBs based on a second percentage of the total TB coded bit number.

29. The baseband processor of claim 26, wherein the baseband processor is further configured to determine a parameter to encode the unequal protection among the different TBs of the physical layer encapsulation based on a media access control (MAC) control element (MAC CE), a radio resource control (RRC) signaling, or a higher layer signaling.

30.-43. (canceled)

44. A method of a network entity comprising:
processing, via a processor, a physical layer transmission comprising different transport blocks (TBs) multiplexed into a physical layer encapsulation with an unequal protection among the different TBs; and
transmitting, via the processor, the physical layer transmission to transmitter circuitry that transmits the physical layer transmission based on four or less spatial layers in a next generation (NR) network.

45. The method of claim 44, further comprising:
encoding a first TB of the different TBs based on a first bit or a least significant bit that is more reliable than other bits of a constellation point and a second TB of the different TBs based on one or more of the other bits of the constellation point to generate the unequal protection among the different TBs.
